(19) United States
(12) Patent Application Publication
(10) Pub. No.: US 2026/0114281 A1
(43) Pub. Date: Apr. 23, 2026

(54) FRAME CONFIGURED TO SUPPORT COOLING AND SHIELDING FOR AN INTEGRATED CIRCUIT DEVICE

(71) Applicant: QUALCOMM Incorporated, San Diego, CA (US)

(72) Inventors: Le GAO, San Diego, CA (US); Youmin YU, Escondido, CA (US); Nader NIKFAR, San Diego, CA (US); Mario SANCHEZ, San Diego, CA (US)

(21) Appl. No.: 18/919,939

(22) Filed: Oct. 18, 2024

(51) Int. Cl. H01L 23/427; H01L 21/50; H01L 23/00; H01L 23/10; H01L 23/498; H01L 23/552

(52) U.S. Cl. CPC H10W 40/73; H10W 42/20; H10W 76/60; H10W 95/00; H10W 70/60; H10W 90/736

(57) ABSTRACT

Various aspects of the present disclosure generally relate to an integrated circuit device, and to heat management and/or electromagnetic interference (EMI) management associated with an integrated circuit device. A device includes a two-phase thermal management device, and a frame coupled to the two-phase thermal management device. The frame includes an opening, and the frame and the two-phase thermal management device define a cavity. The device also includes an EMI shield structure coupled to the two-phase thermal management device via an EMI shield gasket. At least a portion of the EMI shield structure is positioned within the cavity.

### FIELD

Various features relate to integrated circuit devices, and more particularly, to heat management and/or electromagnetic interference (EMI) management associated with an integrated circuit device.

### DESCRIPTION OF RELATED ART

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

In state-of-the-art electronic devices, there is generally an expectation that integrated device packages have a small form factor, a low cost, a tight power budget, and high performance. These various goals are often in conflict. For example, electronic devices, such as mobile devices, include a middle frame or inner frame configured to provide structural support to the electronic device and/or one or more electrical components of the electronic device. The one or more electrical components, such as a semiconductor die that includes an integrated circuit (IC), can generate heat that can cause overheating at the electronic device. To alleviate the heat produced by the IC, a heat dissipation scheme may be implemented at the electronic device. Additionally, an IC of the electronic device can be susceptible to electromagnetic interference (EMI). To combat EMI, an EMI shield is typically provided that covers and shields the IC from the EMI.

Conventional efforts to address heat management and EMI management are complex and costly. For example, heat management solutions and EMI management solutions can increase a size of the electronic device, increase an internal thermal resistance of the electronic device, increase an assembly time and cost of the electronic device, and/or reduce a reliability of the electronic device.

### SUMMARY

Various features relate to integrated circuit devices.

One example provides a device that includes a two-phase thermal management device, and a frame coupled to the two-phase thermal management device. The frame includes an opening. The frame and the two-phase thermal management device define a cavity. The device also includes an electromagnetic interference (EMI) shield structure coupled to the two-phase thermal management device via an EMI shield gasket. At least a portion of the EMI shield structure is positioned within the cavity.

Another example provides a method of fabrication that includes obtaining a frame coupled to a two-phase thermal management device. The frame includes an opening. The frame and the two-phase thermal management device define a cavity. The method also includes coupling an EMI shield structure to the two-phase thermal management device via an EMI shield gasket, such that at least a portion of the EMI shield structure is positioned within the cavity.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a cross-sectional profile view of an exemplary device that includes a frame configured to support shielding for an integrated circuit device.

FIG. 2 illustrates a cross-sectional profile view of another exemplary device that includes a frame configured to support shielding for an integrated circuit device.

FIG. 3A illustrates a first part of an exemplary sequence for fabricating an exemplary device that includes a frame configured to support shielding for an integrated circuit device.

FIG. 3B illustrates a second part of an exemplary sequence for fabricating an exemplary device that includes a frame configured to support shielding for an integrated circuit device.

FIG. 4A illustrates a first part of an exemplary sequence for fabricating an exemplary device that includes a frame configured to support shielding for an integrated circuit device.

FIG. 4B illustrates a second part of an exemplary sequence for fabricating an exemplary device that includes a frame configured to support shielding for an integrated circuit device.

FIG. 5 illustrates an exemplary flow diagram of a method of fabrication for a device that includes a frame configured to support shielding for an integrated circuit device.

FIG. 6 illustrates various electronic devices that may integrate an exemplary frame configured to support shielding for an integrated circuit device described herein.

FIG. 7 illustrates a block diagram of a particular electronic device that may integrate an exemplary frame configured to support shielding for an integrated circuit device described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure. As another example, various devices and structures disclosed herein are illustrated schematically. Such schematic representations are not to scale and are generally intentionally simplified. To illustrate, integrated devices can have many tens or hundreds of contacts and corresponding interconnections; however, a very small number of such contacts and interconnects are illustrated herein to highlight features or aspects of the disclosure without unduly complicating the drawings.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

In some drawings, multiple instances of a particular type of feature are shown. In some circumstances, fewer than all of such features may be identified using a reference number. For example, a single reference number may be shown and associated with a representative instance of the feature so as not to obscure other aspects of the drawings.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

Improvements in manufacturing technology and demand for lower cost and more capable electronic devices has led to increasing complexity of integrated circuits (ICs). Often, more complex ICs have more complex interconnection schemes to enable interaction between ICs of a device. The number of interconnect levels for circuitry has substantially increased due to the large number of devices that are now interconnected in a state-of-the-art electronic device, such as a state-of-the-art mobile application device.

These interconnections include back-end-of-line (BEOL) interconnect layers, which may refer to the conductive interconnect layers for electrically coupling to front-end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middle-of-line (MOL) interconnect layers, which interconnect to the FEOL active devices of an IC.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

State-of-the-art electronic devices (e.g., portable computing devices, mobile communication devices, wearable devices, special purpose computing devices, etc.) demand a small form factor, low cost, a tight power budget, and high electrical performance. Integrated circuit package design has evolved to meet these divergent goals. One approach to reducing package size is to integrate multiple dies (e.g., multiple semiconductor dies) within a single package. One example of a multi-die package is a two-dimensional (2D) package architecture, in which two or more dies are coupled to a package substrate side-by-side with one another. Dies in this configuration can interact with one another (e.g., via die-to-die connections) and with off-package devices (e.g., via off-package connections). A challenge of such configurations is that die-to-die and off-package connections have different design criteria. For example, off-package connections are generally larger (e.g., in terms of line width, line spacing, etc.) than is needed for die-to-die connections. Various workarounds have been used to address this size difference. For example, additional devices (e.g., interposer devices or bridge die) can be added to a package to route die-to-die connections using smaller lines. As another example, additional layers or a separate stacked substrate can be added to the package substrate to provide die-to-die connection and redistribution routing to connect to off-package connections.

Another approach to reducing package size is a 2.5D architecture, in which two or more devices are positioned side-by-side with one another on the package substrate, and one or more additional devices are stacked on at least one of the side-by-side devices. To illustrate, a stacked die arrangement can be coupled to a package substrate side-by-side with another die, a passive device, another die stack, etc. Stacked die schemes and chiplet architectures are becoming more common as significant power performance area (PPA) yield enhancements are demonstrated for stacked die and chiplet architecture product lines.

A three-dimensional integrated circuit (3D IC) includes a set of stacked and interconnected dies. Generally, a 3D IC architecture can achieve higher performance, increased functionality, lower power consumption, and/or smaller footprint, as compared to providing the same circuitry in a monolithic die or in a two-dimensional (2D) IC structure.

Aspects of the present disclosure are directed to a frame configured to support shielding for an integrated circuit device. In some aspects, a device that includes a frame, such as a middle frame, coupled to a two-phase thermal management device. The frame and two-phase thermal management device define a cavity having an opening in the frame. The device also includes an electromagnetic interference (EMI) shield gasket and an EMI shield structure coupled to the two-phase thermal management device. To illustrate, the EMI shield structure is coupled to the two-phase thermal management device via the EMI shield gasket such that at least a portion of the EMI shield structure is positioned within the cavity (e.g., within the frame). In some aspects, an integrated circuit (IC) device (e.g., a semiconductor IC device) and a thermal interface material (TIM) can be coupled to the two-phase thermal management device, and an EMI shield structure can be in contact with the EMI shield gasket. The EMI shield structure may include an opening through which the TIM is thermally coupled to the two-phase thermal management device. The disclosed device with the frame configured to support shielding for an integrated circuit device may provide structural support for the device, reduce or eliminate package warpage, and/or reduce or eliminate interference due to radio waves, electromagnetic fields, and/or electrostatic fields around the die. Additionally, or alternatively, the disclosed device having the frame provides a reduced number of thermal stack up layers between the IC device and the two-phase thermal management device as compared to conventional cooling schemes, thereby providing fewer thermal layers, less thermal resistance, and improved heat dissipation performance. Additionally, the present configurations provide for a reduced thickness and reduced assembly time as compared to conventional devices having heat management and EMI management.

### Exemplary Device Including a Frame Configured to Support Shielding for an IC Device

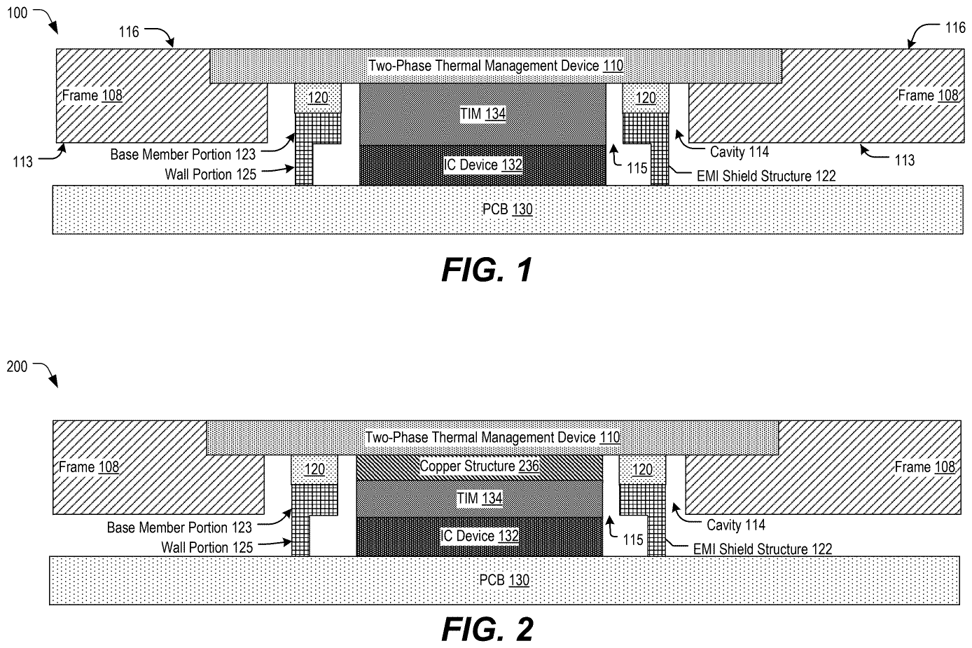

FIG. 1 illustrates a cross-sectional profile view of an exemplary device 100 that includes a frame configured to support shielding for an integrated circuit device. In the implementation shown in FIG. 1, the device 100 includes a frame 108, a two-phase thermal management device 110, an EMI shield gasket 120, an EMI shield structure 122, a printed circuit board (PCB) 130, an IC device 132 (e.g., one or more semiconductor IC devices), and a TIM 134.

The frame 108 is configured to support or be coupled to one or more components of the device 100. For example, the frame may be configured to support and/or be coupled to the two-phase thermal management device 110, the EMI shield gasket 120, the EMI shield structure 122, the PCB 130, the IC device 132, the TIM 134, or a combination thereof, as described further herein. Additionally, or alternatively, the frame 108 may be configured to support and/or be coupled to a housing, a cover, a power management integrated circuit (PMIC), a heat spreader (e.g., a graphite heat spreader), a display screen, a panel or plate, a battery, or a combination thereof, as described further herein at least with reference to FIG. 7. For example, the PMIC may be coupled to the PCB 130, positioned between the PCB 130 and a cover (e.g., a back cover), or a combination thereof. As another example, the heat spreader may be coupled to and positioned between the two-phase thermal management device 110 and the display screen.

In some implementations, the device 100 includes an electronic device, such as a mobile phone or a tablet, that has a housing. For example, the housing may include one or more panels or covers, such as a front panel (e.g., a front display) and a back panel (e.g., a back cover). In some such implementations, the frame 108 may include a middle frame or inner frame of the device 100. In some aspects, the frame 108 (e.g., the middle frame) of an electronic device (e.g., a mobile phone) refers to a connection area between a front panel (of the housing) and a back cover (of the housing) of the electronic device. For example, the middle frame may be configured to couple to (or be coupled to) the front panel and the back cover. In some implementations, the middle frame forms a portion of the housing.

The frame 108 includes one or more surfaces. For example, the frame 108 includes a surface 113 that defines an opening 115. To illustrate, the opening 115 may be associated with a through channel of the frame 108. As another example, the frame 108 includes a surface 116 that includes a recess or cutout that is configured to receive the two-phase thermal management device 110. The frame 108 may include or be formed from aluminum, an aluminum alloy, stainless steel, or titanium, as illustrative, non-limiting examples.

The two-phase thermal management device 110 is coupled to the frame 108. For example, the two-phase thermal management device 110 may be positioned within an opening (defined by a surface of the frame 108 that is opposite to the surface 113) or within the through channel of the frame 108. The two-phase thermal management device 110 may be coupled or secured to the frame 108 by an adhesive, a fastener, or a combination thereof, as illustrative, non-limiting examples. In some implementations, the frame 108 and the two-phase thermal management device 110 define a cavity 114 that is accessible via the opening 115. For example, the frame 108 may define one or more walls of the cavity 114 and the two-phase thermal management device 110 may define a bottom of the cavity 114.

The two-phase thermal management device 110 is configured to be coupled (e.g., thermally coupled) to one or more components of the device 100. For example, the two-phase thermal management device 110 may be thermally coupled to the IC device 132, as described further herein. To further illustrate, the two-phase thermal management device 110 can be coupled to the IC device 132 via the TIM 134.

In some implementations, the two-phase thermal management device 110 may include a sealed two-phase thermal management device. In a particular aspect, the two-phase thermal management device 110 includes a condenser, an evaporator, and a working fluid. For example, the two-phase thermal management device 110 can include a vapor chamber, one or more heat pipes, a thermosyphon, or a combination thereof. In some implementations, a working fluid is added in a volume (or cavity) defined by the two-phase thermal management device 110. The working fluid can include water, acetone, an alcohol, one or more additives, or a combination thereof, as illustrative, non-limiting examples. In some implementations, the composition of the working fluid, an internal pressure of the two-phase thermal management device 110, or both, may be set to achieve a target boiling point of the working fluid.

In an example, the two-phase thermal management device 110 is in thermal communication with a heat source (e.g., the IC device 132) coupled to (e.g., proximate to) the two-phase thermal management device 110. In a particular aspect, the heat source includes one or more processors, a CPU, a GPU, an audio processor, a video processor, a display, or a combination thereof. Heat produced by the heat source may warm at least a portion of the two-phase thermal management device 110 and cause a phase change of the working fluid from liquid to vapor. For example, the two-phase thermal management device 110 may include one or more evaporator portions where heat from the heat source is applied to the working fluid and the working fluid undergoes a phase change from liquid to vapor. As the working fluid (e.g., as vapor) travels away from the evaporator portion, the working fluid moves to one or more cooler condenser portions of the two-phase thermal management device 110 where the working fluid is condensed from vapor to liquid.

According to some implementations, the two-phase thermal management device 110 is in thermal communication with one or more heatsinks. The one or more heatsinks can include an ambient environment, a heat spreader, or both. A region (e.g., the condenser portion) of the two-phase thermal management device 110, cooled by a heatsink, can cause the working fluid in the region to condense. The working fluid (e.g., as liquid) flows back to the one or more evaporator portions of the two-phase thermal management device 110, such as via capillary action of a wicking portion of the two-phase thermal management device 110.

The EMI shield gasket 120 is coupled to or in contact with the two-phase thermal management device 110. For example, in some implementations, the EMI shield gasket 120 is in contact with the two-phase thermal management device 110. As another example, the EMI shield gasket 120 is coupled, via an adhesive material, to the two-phase thermal management device 110. The adhesive material may include an epoxy, as an illustrative, non-limiting example. At least a portion of the EMI shield gasket 120 is positioned within the cavity 114. In a particular aspect, an entirety of the EMI shield gasket 120 is positioned within the cavity 114.

The EMI shield gasket 120 may be made of a foam, a tape, an electrically conductive elastomer, or a combination thereof, that is configured to provide sealing, thermal insulation, and/or shielding against conducted or radiated EMI. For example, the EMI shield gasket 120 may include metal or metal-coated particles, such as including nickel or iron alloys, copper, aluminum, silver, or a combination thereof, that provide electrical conductivity. Additionally, or alternatively, the EMI shield gasket 120 is configured to seal a gap between two surfaces, such as a surface of the two-phase thermal management device 110 and a surface of the EMI shield structure 122. In some implementations, the EMI shield gasket 120 is coupled to or includes an adhesive (e.g., an adhesive backing) to enable the EMI shield gasket 120 to be coupled to a surface.

The EMI shield structure 122 is coupled to the EMI shield gasket 120, the PCB 130, or a combination thereof. The EMI shield structure 122 includes a base member portion 123 and one or more wall portions 125 (herein after referred to as “the wall portion 125”). The base member portion 123 is configured to be coupled to (and/or in contact with) the EMI shield gasket 120. Additionally, or alternatively, the base member portion 123 defines a first opening on a first side (that is coupled to the EMI shield gasket 120) of the base member portion 123, a second opening on a second side of the base member portion 123, or a combination thereof. The wall portion 125 extends from the second side of the base member portion 123. The wall portion 125 (e.g., an end surface of the wall portion 125) may be coupled to and/or in contact with the PCB 130. For example, the wall portion 125 (e.g., the EMI shield structure 122) may be coupled to the PCB 130 via a solder connection and/or a contact or interface of the PCB 130. An end surface of the wall portion 125 may define a third opening. In some implementations, the EMI shield structure 122 includes or has a through channel that extends from the first opening to the third opening.

In some implementations, at least a portion of the base member portion 123 of the EMI shield structure 122 is positioned within the cavity 114. In a particular example, an entirety of the base member portion 123 of the EMI shield structure 122 is positioned within the cavity 114. Additionally, or alternatively, at least a portion of the IC device 132, at least a portion of the TIM 134, or a combination thereof, may be positioned between the first opening of the base member portion 123 of the EMI shield structure 122 and the second opening of the base member portion 123 of the EMI shield structure 122.

The EMI shield structure 122 may be electrically grounded to a chassis ground or another electrical ground path of the device 100. In some such implementations, the EMI shield structure 122 can reduce or eliminate radio waves, electromagnetic fields, and/or electrostatic fields around the IC device 132. For example, the EMI shield structure 122 may isolate the IC device 132 by creating a Faraday cage on the PCB 130 and around the IC device 132.

The IC device 132 includes one or more IC devices (e.g., one or more semiconductor IC devices). In a particular aspect, the IC device 132 includes one or more processors, such as a central processing unit (CPU), a graphics processing unit (GPU), an audio processor, a video processor, a display processor, a modem, or a combination thereof. The IC device 132 can be coupled to the PCB 130. For example, the IC device 132 may be electrically coupled to the PCB 130. To illustrate, the IC device 132 may be electrically coupled to the PCB 130 by one or more conductive interconnects (CIs), which may include tin, silver, copper, or a combination thereof, as illustrative, non-limiting examples.

The IC device 132 can include integrated circuitry, such as a plurality of transistors and/or other circuit elements arranged and interconnected to form logic cells, memory cells, etc. Components of the integrated circuitry can be formed in and/or over a semiconductor substrate. Different implementations can use different types of transistors, such as a field effect transistor (FET), planar FET, finFET, a gate all around FET, or mixtures of transistor types. In some implementations, a front end-of-line (FEOL) process may be used to fabricate the integrated circuitry in and/or over the semiconductor substrate.

The IC device 132 may include or correspond to particular IC devices that can be arranged and interconnected as a three-dimensional (3D) IC device. In some implementations, the IC device 132 includes one or more microcontrollers, application specific integrated circuits (ASICs), field programmable gate arrays (FPGAs), central processing units (CPUs) having one or more processing cores, processing systems, system on chip (SoC), or other circuitry and logic configured to facilitate the operations of the IC device 132. Additionally, or alternatively, the IC device 132 may include a memory, such as a static random-access memory (SRAM), a dynamic random-access memory (DRAM), flash memory, read-only memory (ROM), programmable read-only memory (PROM), erasable programmable read-only memory (EPROM), electrically erasable programmable read-only memory (EEPROM), a solid-state storage device (SSD), or a combination thereof.

In some implementations, the IC devices are electrically connected to, or integrated with, respective substrates. For example, the IC device 132 may include or be electrically connected (e.g., via one or more contacts or interconnects) to a substrate. Any of the conductive interconnects and contacts described herein can include, for example, microbumps, conductive pillars, conductive pads (e.g., for pad-to-pad bonding), or other similar chiplet-to-chiplet interconnect contacts used for 3D chiplet stacking. Additionally, or alternatively, the IC devices 132 may include multiple IC devices that are arranged side-by-side.

The TIM 134 is coupled to or in contact with the IC device 132, the two-phase thermal management device 110, or a combination thereof. In some implementations, at least a portion of the TIM 134 is positioned within the cavity 114. In a particular aspect, an entirety of the TIM 134 is positioned within the cavity 114. Illustrative, non-limiting examples of different types of TIMs include thermal pads, thermal grease, thermally conductive compounds, and/or gap fillers. In some implementations, the TIM 134 may be referred to as an external TIM, since it is external to the IC device 132.

It should be understood that the device 100 may include additional components, other components, fewer components, or a combination thereof, to support the functionality described herein. As non-limiting examples, the device 100 may include additional IC devices, additional layers, additional dies, additional packages, additional interconnects, additional structures, other components, different components, or a combination thereof, to support the functionality and technical advantages disclosed herein.

During operation of the device 100, when the IC device 132 produces heat, working fluid in an evaporator portion of the two-phase thermal management device 110 that is closer to the IC device 132 undergoes a phase change from liquid to vapor. As the working fluid (as vapor) spreads away from the IC device 132 and enters a condenser portion of the two-phase thermal management device 110, the working fluid condenses back to a liquid and flows back to the evaporator portion of the two-phase thermal management device 110. In some examples, a heat sink or condenser above the condenser portion of the two-phase thermal management device 110 cools the condenser portion to cause the working fluid to condense back to a liquid. Additionally, or alternatively, during operation of the device 100, the EMI shield structure 122, the EMI shield gasket 120, or a combination thereof, may reduce or eliminate radio waves, electromagnetic fields, and/or electrostatic fields around the IC device 132. For example, the EMI shield structure 122, the EMI shield gasket 120, or a combination thereof, may receive the radio waves, the electromagnetic fields, and/or the electrostatic fields and provide a path to a ground of the device 100.

The device 100 thus experiences improved thermal management as compared to other devices that do not include the two-phase thermal management device 110. A technical advantage of the two-phase thermal management device 110 includes improved performance of the IC device 132, improved heat dissipation of the device 100, or both. Additionally, or alternatively, the frame 108 may provide structural support for the device 100 and reduce or eliminate warpage of material surrounding the IC device 132. The frame 108 and/or the EMI shield structure 122 (having one or more openings in the base member portion 123) may also provide an additional advantage of enabling a reduced, compact size of the device 100 by enabling the EMI shield gasket 120 and/or at least a portion of the EMI shield structure 122 to be positioned within the cavity 114. Additionally, or alternatively, the EMI shield gasket 120 and/or the EMI shield structure 122 may beneficially reduce or eliminate radio waves, electromagnetic fields, and/or electrostatic fields around the IC device 132.

In a particular implementation, the device 100 includes a two-phase thermal management device (e.g., the two-phase thermal management device 110), and a frame (e.g., the frame 108) coupled to the two-phase thermal management device. The frame includes an opening (e.g., the opening 115). The frame and the two-phase thermal management device define a cavity (e.g., the cavity 114). The device also includes an EMI shield structure (e.g., the EMI shield structure 122) coupled to the two-phase thermal management device via an EMI shield gasket (e.g., the EMI shield gasket 120). At least a portion of the EMI shield gasket may be positioned within the cavity. Additionally, or alternatively, at least a portion of the EMI shield structure may be positioned within the cavity.

FIG. 2 illustrates a cross-sectional profile view of a particular implementation of a device 200 that includes a frame configured to support shielding for an integrated circuit device. The device 200 of FIG. 2 includes many of the same components and features as are described above with reference to FIG. 1. Such components and features are physically and operationally the same as described above with reference to FIG. 1 and are labeled in FIG. 2 using the same reference numbers.

In the example shown in FIG. 2, the device 200 includes a copper structure 236, such as a copper layer, a copper step, or a copper pedestal. The copper structure 236 may be coupled to or in contact with the two-phase thermal management device 110, the TIM 134, or a combination thereof. For example, the copper structure 236 may be welded to the two-phase thermal management device 110. In some implementations, an entirety of the copper structure 236 is positioned within the cavity 114. The copper structure 236 may be configured to operate as a heat spreader or thermal mass between the IC device 132 and the two-phase thermal management device 110 to improve or define the size of the two-phase thermal management device that operates as an evaporator portion.

As described with reference to FIG. 2, the device 200 including the two-phase thermal management device 110 has improved performance of the IC device 132, improved heat dissipation of the device 100, or both. Additionally, or alternatively, the frame 108 may provide structural support for the device 100 and reduce or eliminate warpage of material surrounding the IC package 132. The frame 108 and/or the EMI shield structure 122 (having one or more openings in the base member portion 123) may also provide an additional advantage of enabling a reduced, compact size of the device 100 by enabling the EMI shield gasket 120 and/or at least a portion of the EMI shield structure 122 to be positioned within the cavity 114. Additionally, or alternatively, the EMI shield gasket 120 and/or the EMI shield structure 122 may beneficially reduce or eliminate radio waves, electromagnetic fields, and/or electrostatic fields around the IC device 132.

While FIGS. 1-2 illustrate example devices 100 and 200, it is noted that the device 100 or 200 can be integrated with or included within a wide variety of other devices. For example, the device 100 or 200 can include or be coupled to one or more components, such as a PMIC, an application processor, a modem, a radio frequency (RF) device, a passive device, a filter, a capacitor, an inductor, a transmitter, a receiver, a gallium arsenide (GaAs) based integrated device, a surface acoustic wave (SAW) filter, a bulk acoustic wave (BAW) filter, a silicon (Si) based integrated device, a silicon carbide (SiC) based integrated device, a memory, power management processor, and/or combinations thereof. In such implementations, the device 100 or 200 (e.g., the IC device 132) can operate as any of these components (or a combination of these components) that includes active circuitry.

In some implementations, the device 100 or 200 can be integrated in a smartphone, a tablet computer, a fixed location terminal device, a vehicle (e.g., an automobile), a wearable electronic device, a laptop computer, or some combination thereof, as described in more detail below with reference to FIG. 6. In some other implementations, the device 100 or 200 can be integrated into a mobile communication device, as described in more detail below with reference to FIG. 7.

### Exemplary Sequence for Fabricating a Device Including a Frame Configured to Support Shielding for an IC Device

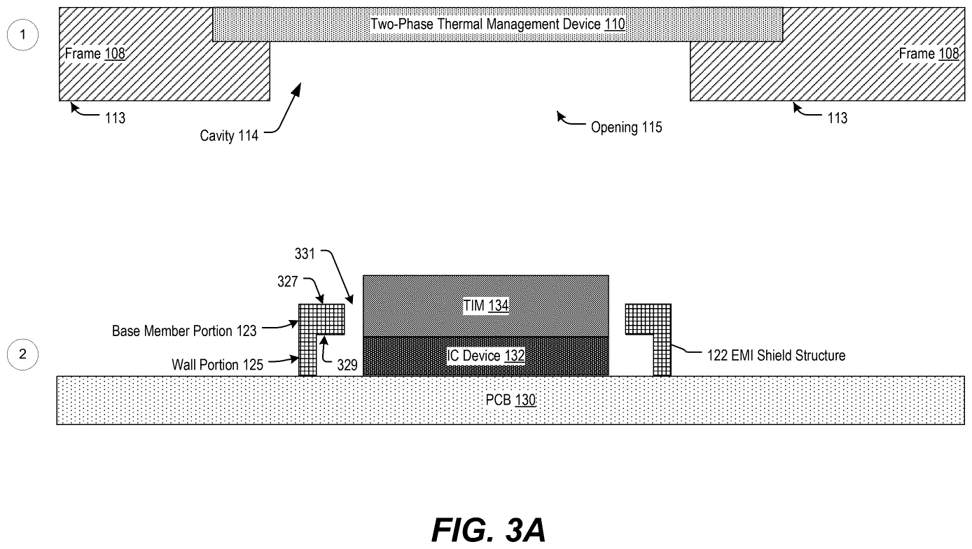

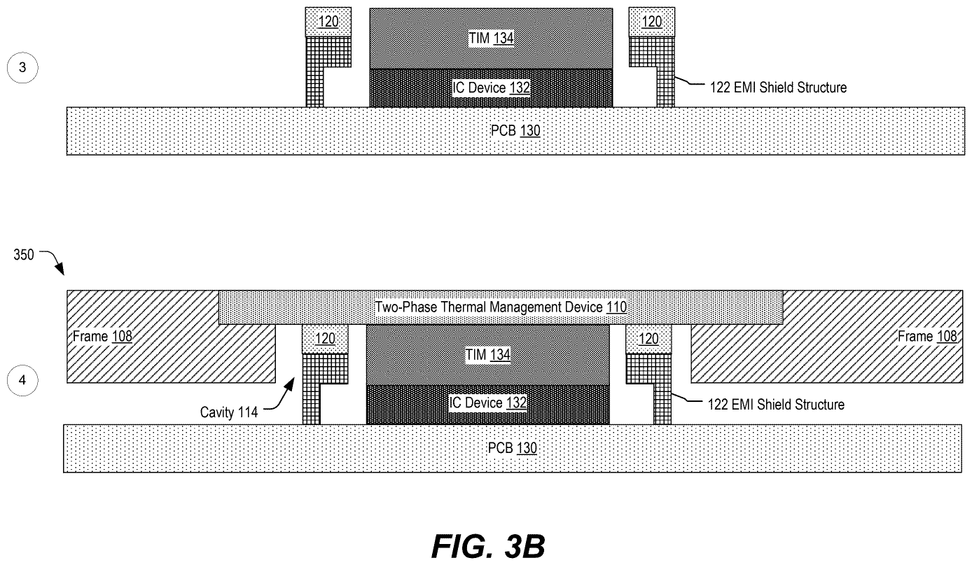

In some implementations, fabricating a device (e.g., any of the devices 100 or 200) including a frame configured to support shielding for an integrated circuit device includes several processes. FIGS. 3A-B illustrate an exemplary sequence for fabricating or providing a device that includes a frame configured to support shielding for an integrated circuit device, as described with reference to FIG. 1. In some implementations, the sequence of FIGS. 3A-B may be used to provide one or more of the device 100 of FIG. 1.

It should be noted that the sequence of FIGS. 3A-B may combine one or more stages in order to simplify and/or clarify the sequence for providing or fabricating a device. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIGS. 3A-B. Each of the various stages of the sequence illustrated in FIGS. 3A-B shows one or more aspects of a device including a frame configured to support shielding for an integrated circuit device being formed.

Stage 1 of FIG. 3A illustrates a state after a two-phase thermal management device 110 is coupled to a frame 108. For example, the two-phase thermal management device 110 may be positioned in a recess or cutout of the frame 108. The frame 108 includes a surface 113 that defines an opening 115. In some implementations, the frame 108 and the two-phase thermal management device 110 define a cavity 114 that is accessible via the opening 115.

As part of Stage 1, the frame 108 and the two-phase thermal management device 110 may be obtained. In some implementations, the frame 108 and the two-phase thermal management device 110 are obtained separately and then the two-phase thermal management device 110 is coupled to the frame 108. Alternatively, the frame 108 and the two-phase thermal management device 110 may be obtained in a coupled state—e.g., obtained with the two-phase thermal management device 110 already coupled to the frame 108.

Stage 2 illustrates a state after an EMI shield structure 122 is coupled to a PCB 130. The EMI shield structure 122 may be coupled to the PCB 130 via a solder connection and/or a contact or interface of the PCB 130. The EMI shield structure 122 includes a base member portion 123 and a wall portion 125 that extends from the base member portion 123. The base member portion 123 includes a first surface 327 and a second surface 329. The base member portion 123 may define a channel 331 (e.g., a through channel) that extends between the first surface 327 and the second surface 329.

In some implementations, as part of Stage 2, the PCB 130 and the EMI shield structure 122 are obtained. The PCB 130 may be coupled to the IC device 132 and the TIM 134. For example, the PCB 130 may be obtained with the IC device 132 and the TIM 134 coupled to the PCB 130 such that the IC device 132 is positioned between the PCB 130 and the TIM 134. Alternatively, the PCB 130 and the IC device 132 may be obtained separately and the IC device 132 may then be coupled to the PCB 130. After the IC device 132 is coupled to the PCB 130, the TIM 134 may be coupled to or deposited on the IC device 132 such that the TIM 134 is thermally coupled to the IC device 132.

In some implementations, as part of Stage 2, the EMI shield structure 122 may be positioned with respect to the PCB 130. For example, the EMI shield structure 122 may be arranged such that the wall portion 125 is positioned between the PCB 130 and the base member portion 123, and the EMI shield structure 122 may be moved toward the PCB 130 such that at least a portion of the TIM 134, or at least a portion of the TIM 134 and a portion of the IC device 132, pass through the channel 331.

Stage 3 of FIG. 3B illustrates a state after an EMI shield gasket 120 is coupled to the EMI shield structure 122. For example, as part of Stage 3, the EMI shield gasket 120 may be obtained and coupled to the first surface 327 of the base member portion 123 of the EMI shield structure 122.

Stage 4 illustrates a state after the two-phase thermal management device 110 (from Stage 1 of FIG. 3A) is coupled to the EMI shield gasket 120. Additionally, Stage 4 may also illustrate a state after the two-phase thermal management device 110 (from Stage 1 of FIG. 3A) is coupled to the TIM 134. For example, the two-phase thermal management device 110 may be thermally coupled to the TIM 134 and thereby be thermally coupled to the IC device 132.

Formation of the device 350 (e.g., a device including the frame 108 configured to support shielding for an integrated circuit device) is complete after Stage 5 of FIG. 3B. The device 350 may include or correspond to the device 100 of FIG. 1.

Although certain Stages are illustrated in FIGS. 3A-B in forming the device 350, other processes can be included in the fabrication of the device 350 without departing from the scope of the subject disclosure. For example, fabricating the device 350 can include coupling the EMI shield structure 122 to the PCB 130 prior to the TIM 134 being coupled to the IC device 132.

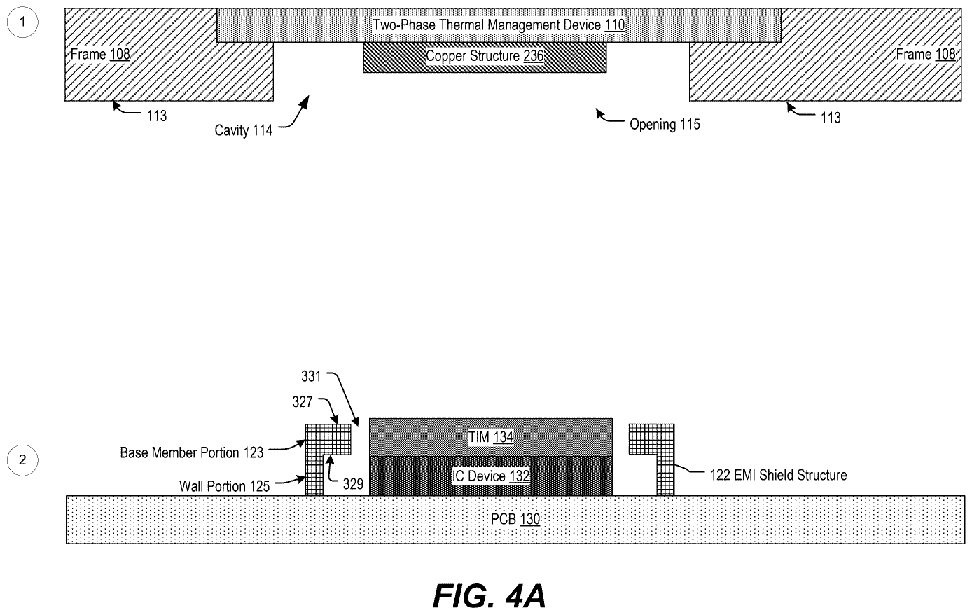

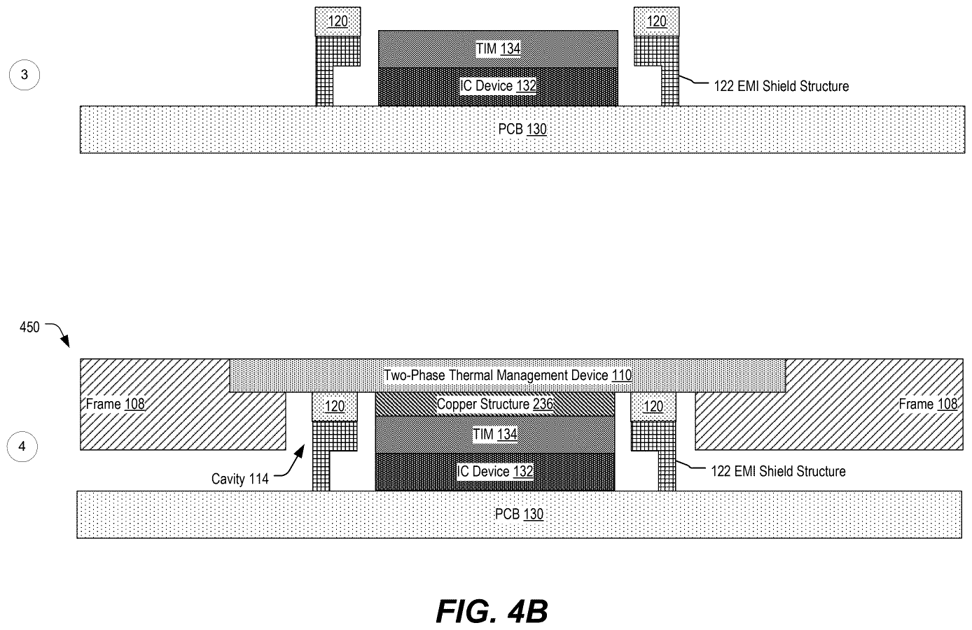

FIGS. 4A-B illustrate an exemplary sequence for fabricating or providing a device that includes a frame configured to support shielding for an integrated circuit device, as described with reference to FIG. 2. In some implementations, the sequence of FIGS. 4A-B may be used to provide one or more of the device 200 of FIG. 2.

It should be noted that the sequence of FIGS. 4A-B may combine one or more stages in order to simplify and/or clarify the sequence for providing or fabricating a device. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIGS. 4A-B. Each of the various stages of the sequence illustrated in FIGS. 4A-B shows one or more aspects of a device including a frame configured to support shielding for an integrated circuit device being formed.

Stage 1 of FIG. 4A illustrates a state after a two-phase thermal management device 110 is coupled to a frame 108 and after a copper structure 236 is coupled to the two-phase thermal management device 110. For example, the copper structure 236 may be deposited or welded to the two-phase thermal management device 110.

Stage 2 illustrates a state after an EMI shield structure 122 is coupled to a PCB 130. Stage 2 of FIG. 4A may include or correspond to Stage 2 of FIG. 3A.

Stage 3 of FIG. 4B illustrates a state after an EMI shield gasket 120 is coupled to the EMI shield structure 122. Stage 3 of FIG. 4B may include or correspond to Stage 3 of FIG. 3B.

Stage 4 illustrates a state after the two-phase thermal management device 110 (from Stage 1 of FIG. 4A) is coupled to the EMI shield gasket 120. Additionally, Stage 4 may also illustrate a state after the copper structure 236 (from Stage 1 of FIG. 4A) is coupled to the TIM 134. For example, the copper structure 236 may be thermally coupled to the TIM 134 and, accordingly, the two-phase thermal management device 110 may thereby be thermally coupled to the IC device 132 via the copper structure 236 and the TIM 134.

Formation of the device 450 (e.g., a device including a frame configured to support shielding for an integrated circuit device) is complete after Stage 4 of FIG. 4B. The device 450 may include or correspond to the device 200 of FIG. 2.

Although certain Stages are illustrated in FIGS. 4A-B in forming the device 450, other processes can be included in the fabrication of the device 450 without departing from the scope of the subject disclosure. For example, fabricating the device 450 can include coupling the EMI shield structure 122 to the PCB 130 prior to the TIM 134 being coupled to the IC device 132. Additionally, or alternatively, as another example, Stage 1 of FIG. 3A may be included prior to Stage 1 of FIG. 4A.

### Exemplary Flow Diagram of a Method for Fabricating a Device Including a Frame Configured to Support Shielding for an IC Device

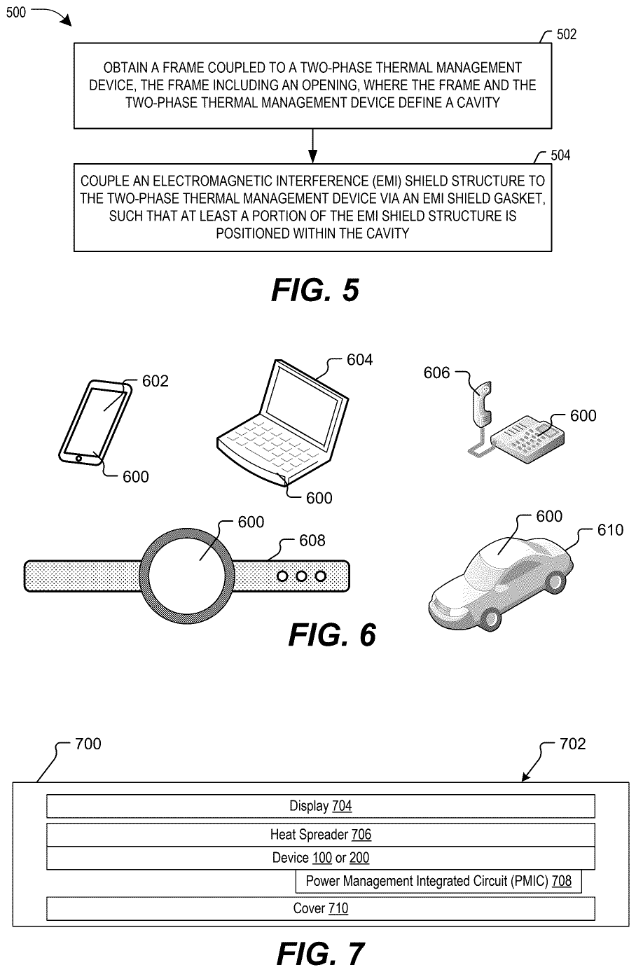

In some implementations, fabricating a device including a frame configured to support shielding for an integrated circuit device includes several processes. FIG. 5 illustrates an exemplary flow diagram of a method 500 of fabricating an illustrative device that includes a frame configured to support shielding for an integrated circuit device. In a particular aspect, one or more operations of the method 500 are performed by one or more processors of a fabrication system. In some implementations, operations of the method 500 may be stored as instructions by a non-transitory computer-readable storage medium, and the instructions may be executable by at least one processor to cause the at least one processor to initiate, perform or control operations of the method 500. In some implementations, the method 500 of FIG. 5 may be used to provide or fabricate any of the device 100 of FIG. 1 or the device 200 of FIG. 2.

It should be noted that the method 500 of FIG. 5 may combine one or more processes in order to simplify and/or clarify the method for providing or fabricating a device. In some implementations, the order of the processes may be changed or modified.

The method 500 includes, at block 502, obtaining a frame coupled to a two-phase thermal management device. For example, Stage 1 of FIGS. 3A and 4A illustrate and describe examples of obtaining the frame 108 coupled to the two-phase thermal management device 110. The frame includes an opening, and the frame and the two-phase thermal management device define a cavity. For example, the opening and the cavity may include or correspond to the opening 115 and the cavity 114, respectively.

At block 504, the method 500 includes coupling an EMI shield structure to the two-phase thermal management device via an EMI shield gasket, such that at least a portion of the EMI shield structure is positioned within the cavity. For example, Stage 4 of FIG. 3B and Stage 4 of FIG. 4B each illustrate and describe examples of coupling the EMI shield gasket 120 to the two-phase thermal management device 110, such that at least a portion of the EMI shield gasket 120 is positioned within the cavity 114.

In some implementations, the method 500 also includes obtaining the EMI shield structure. For example, the EMI shield structure may include or correspond to the EMI shield structure 122. The EMI shield structure may include a base member portion and one or more wall portions. The base member portion and the one or more wall portions may include or correspond to the base member portion 123 and the wall portion 125, respectively. The base member portion may define a first opening on a first side of the base member portion, and a second opening on a second side of the base member portion. The first side of the base member portion may include or correspond to a side having the first surface 327, and the second side of the base member portion may include or correspond to a side having the second surface 329. The one or more wall portions may extend from the second side of the base member portion. In some implementations, the one or more wall portions include multiple wall portions. In some other implementations, the one or more wall portions include a single wall portion.

In some implementations, the method 500 also includes coupling the EMI shield gasket to the first side of the EMI shield structure prior to coupling the EMI shield gasket to the two-phase thermal management device. For example, Stage 3 of FIG. 3B and Stage 3 of FIG. 4B each illustrate and describe examples of coupling the EMI shield gasket 120 to the first side (associated with the first surface 327) of the EMI shield structure 122. In some implementations, coupling the EMI shield structure to the PCB includes passing at least a portion of the TIM through the first opening of the base member portion and the second opening of the base member portion of the EMI shield structure.

In some implementations, the method 500 also includes forming a copper layer within the cavity on a surface of the two-phase thermal management device. For example, Stage 1 of FIG. 4A illustrates and describes examples of forming the copper structure 236 on the surface of the two-phase thermal management device 110 such that the copper structure 236 is positioned within the cavity 114.

In some implementations, the method 500 also includes obtaining a PCB coupled to an IC device (e.g., a semiconductor IC device) and a TIM, where the IC device is positioned between the PCB and the TIM. The method 500 may also include coupling the EMI shield structure to the PCB. For example, Stage 2 of FIG. 3A and Stage 2 of FIG. 4A each illustrate and describe examples of obtaining the PCB 130 coupled to the IC device 132 and the TIM 134.

### Exemplary Electronic Devices

FIG. 6 illustrates various electronic devices that may include or be integrated with a device (that includes a frame configured to support shielding for an integrated circuit device), such as the device 100 or the device 200. For example, a mobile phone device 602, a laptop computer device 604, a fixed location terminal device 606, a wearable device 608, or a vehicle 610 (e.g., an automobile or an aerial device) may include a device 600. The device 600 can include, for example, any of the device 100 or the device 200, and/or any other device that includes a frame configured to support shielding for an integrated circuit device. The devices 602, 604, 606 and 608 and the vehicle 610 illustrated in FIG. 6 are merely exemplary. Other electronic devices may also feature the device 600 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

FIG. 7 illustrates a block diagram of a particular electronic device 700 that may integrate an exemplary frame configured to support shielding for an integrated circuit device described herein. The device 700 may include or correspond to one or more of the devices 602, 604, 606 or 608 or the vehicle 610 (or a device within the vehicle 610).

The device 700 includes a housing 702. The housing 702 may include or define at least a portion of an outer structure of the device 700. The device 700 may also include a display 704, a heat spreader 706, the device 100 or 200, a PMIC 708, and a cover 710. In some implementations, the housing 702 may include the display 704, the frame 108 of the device 100 or 200, the cover 710 (e.g., a front cover or a back cover), one or more panels (e.g., a front panel or a back panel), or a combination thereof.

The heat spreader 706 may be coupled to the device 100 or 200. For example, the heat spreader 706 may be coupled to the frame 108, the two-phase thermal management device 110, or a combination thereof. The display 704 may be coupled to the heat spreader 706. In some implementations, the heat spreader 706 is positioned between the display 704 and the device 100 or 200.

The PMIC 708 may be coupled to the device 100 or 200. For example, the PMIC 708 may be coupled to the PCB 130 of the device 100 or 200. In some implementations, the PCB 130 is positioned between the PMIC 708 and the IC device 132. The cover 710, such as a back cover, may be coupled to the frame 108 (of the device 100 or 200), the PCB 130 (of the device 100 or 200), or a combination thereof. In some implementations, the PMIC 708 is positioned between the PCB 130 and the cover 710.

One or more of the components, processes, features, and/or functions illustrated in FIGS. 1-7 may be rearranged and/or combined into a single component, process, feature or function or embodied in several components, processes, or functions.

Additional elements, components, processes, and/or functions may also be added without departing from the disclosure. It should also be noted FIGS. 1-7 and its corresponding description in the present disclosure is not limited to dies and/or ICs. In some implementations, FIGS. 1-7 and its corresponding description may be used to manufacture, create, provide, and/or produce devices and/or integrated devices. In some implementations, a device may include a die, an integrated device, an embedded multi-chip package, an integrated passive device (IPD), a die package, an IC device, a device package, an IC package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling or electrical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third”, and “fourth” (and/or anything above fourth) is arbitrary. Any of the components described may be the first component, the second component, the third component or the fourth component. For example, a component that is referred to as a second component, may be the first component, the second component, the third component or the fourth component.

The terms “encapsulate”, “encapsulating”, and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component.

A value that is about X-XX, may mean a value that is between X and XX, inclusive of X and XX. The value(s) between X and XX may be discrete or continuous. The term “about ‘value X’”, or “approximately ‘value X’”, as used in the disclosure means within 10 percent of the ‘value X’. For example, a value of about 1 or approximately 1, would mean a value in a range of 0.9-1.1. The term “substantially” is defined as largely but not necessarily wholly what is specified (and includes what is specified; for example, substantially 90 degrees includes 90 degrees and substantially parallel includes parallel), as understood by a person of ordinary skill in the art. In any disclosed implementations, the term “substantially” may be substituted with “within [a percentage] of” what is specified, where the percentage includes 0.1, 1, 5, or 10 percent. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, a device includes a two-phase thermal management device; a frame coupled to the two-phase thermal management device, the frame including an opening, wherein the frame and the two-phase thermal management device define a cavity; and an electromagnetic interference (EMI) shield structure coupled to the two-phase thermal management device via an EMI shield gasket, at least a portion of the EMI shield structure is positioned within the cavity.

Example 2 includes the device of Example 1, where the EMI shield gasket is in contact with the two-phase thermal management device, and an entirety of the EMI shield gasket is positioned within the cavity.

Example 3 includes the device of Example 1 or Example 2, where the EMI shield structure is in contact with the EMI shield gasket.

Example 4 includes the device of Example 3, where the EMI shield structure includes: a base member portion that defines: a first opening on a first side of the base member portion, wherein the first side is coupled to the EMI shield gasket; and a second opening on a second side of the base member portion; and one or more wall portions that extend from the second side of the base member portion.

Example 5 includes the device of Example 4, where an entirety of the base member portion of the EMI shield structure is positioned within the cavity.

Example 6 includes the device of Example 4 or Example 5, and the device also includes a printed circuit board (PCB) coupled to the EMI shield structure.

Example 7 includes the device of Example 6, where the one or more wall portions of the EMI shield structure are coupled to the PCB.

Example 8 includes the device of Example 6 or Example 7, and the device also includes a power management integrated circuit (PMIC) coupled to the PCB; and a cover coupled to the frame, the PCB, or a combination thereof; and wherein the PMIC is positioned between the PCB and the cover.

Example 9 includes the device of any of Examples 4 to 8, and the device also includes a semiconductor integrated circuit (IC) device; and a thermal interface material (TIM) in contact with the semiconductor IC device; and wherein at least a portion of the TIM is positioned within the cavity.

Example 10 includes the device of Example 9, where at least a portion of the TIM, at least a portion of the semiconductor IC device, or a combination thereof, is positioned between the first opening of the base member portion of the EMI shield structure and the second opening of the base member portion of the EMI shield structure.

Example 11 includes the device of any of Examples 1 to 10, and the device also includes a copper structure in contact with the two-phase thermal management device; and wherein an entirety of the copper structure is positioned within the cavity.

Example 12 includes the device of any of Examples 1 to 11, wherein: the two-phase thermal management device includes a condenser, an evaporator, and a working fluid; and the frame includes a middle frame structure.

Example 13 includes the device of any of Examples 1 to 12, the device also includes a heat spreader coupled to the two-phase thermal management device, the frame, or a combination thereof; and a display screen coupled to the heat spreader; and wherein the heat spreader is positioned between the display screen and the two-phase thermal management device.

Example 14 includes the device of any of Examples 1 to 13, where the device includes a portable communication device.

According to Example 15, a method of fabrication includes obtaining a frame coupled to a two-phase thermal management device, the frame including an opening, where the frame and the two-phase thermal management device define a cavity; and coupling an electromagnetic interference (EMI) shield structure to the two-phase thermal management device via an EMI shield gasket, such that at least a portion of the EMI shield structure is positioned within the cavity.

Example 16 includes the method of Example 15, and the method further includes forming a copper structure within the cavity on a surface of the two-phase thermal management device.

Example 17 includes the method of Example 15 or Example 16, and the method further includes obtaining the EMI shield structure that includes: a base member portion that defines: a first opening on a first side of the base member portion; and a second opening on a second side of the base member portion; and multiple wall portions that extend from the second side of the base member portion.

Example 18 includes the method of Example 17, and the method further includes coupling the EMI shield gasket to the first side of the EMI shield structure prior to coupling the EMI shield gasket to the two-phase thermal management device.

Example 19 includes the method of Examples 17 or Example 18, further includes obtaining a printed circuit board (PCB) coupled to a semiconductor integrated circuit (IC) device and a thermal interface material (TIM), the semiconductor IC device is positioned between the PCB and the TIM; and coupling the EMI shield structure to the PCB.

Example 20 includes the method of Example 19, where coupling the EMI shield structure to the PCB includes passing at least a portion of the TIM through the first opening of the base member portion and the second opening of the base member portion of the EMI shield structure.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A device comprising:
a two-phase thermal management device;
a frame coupled to the two-phase thermal management device, the frame including an opening, wherein the frame and the two-phase thermal management device define a cavity; and
an electromagnetic interference (EMI) shield structure coupled to the two-phase thermal management device via an EMI shield gasket, at least a portion of the EMI shield structure is positioned within the cavity.

2. The device of claim 1, wherein:
the EMI shield gasket is in contact with the two-phase thermal management device; and
an entirety of the EMI shield gasket is positioned within the cavity.

3. The device of claim 1, wherein the EMI shield structure is in contact with the EMI shield gasket.

4. The device of claim 3, wherein the EMI shield structure includes:
a base member portion that defines:
a first opening on a first side of the base member portion, wherein the first side is coupled to the EMI shield gasket; and
a second opening on a second side of the base member portion; and
one or more wall portions that extend from the second side of the base member portion.

5. The device of claim 4, wherein an entirety of the base member portion of the EMI shield structure is positioned within the cavity.

6. The device of claim 4, further comprising a printed circuit board (PCB) coupled to the EMI shield structure.

7. The device of claim 6, wherein the one or more wall portions of the EMI shield structure are coupled to the PCB.

8. The device of claim 6, further comprising:
a power management integrated circuit (PMIC) coupled to the PCB; and
a cover coupled to the frame, the PCB, or a combination thereof, and
wherein the PMIC is positioned between the PCB and the cover.

9. The device of claim 4, further comprising:
a semiconductor integrated circuit (IC) device; and
a thermal interface material (TIM) in contact with the semiconductor IC device, and
wherein at least a portion of the TIM is positioned within the cavity.

10. The device of claim 9, wherein at least a portion of the TIM, at least a portion of the semiconductor IC device, or a combination thereof, is positioned between the first opening of the base member portion of the EMI shield structure and the second opening of the base member portion of the EMI shield structure.

11. The device of claim 1, further comprising:
a copper structure in contact with the two-phase thermal management device; and
wherein an entirety of the copper structure is positioned within the cavity.

12. The device of claim 1, wherein:
the two-phase thermal management device includes a condenser, an evaporator, and a working fluid; and
the frame includes a middle frame structure.

13. The device of claim 1, further comprising:
a heat spreader coupled to the two-phase thermal management device, the frame, or a combination thereof; and
a display screen coupled to the heat spreader; and
wherein the heat spreader is positioned between the display screen and the two-phase thermal management device.

14. The device of claim 1, wherein the device includes a portable communication device.

15. A method of fabrication, the method comprising:
obtaining a frame coupled to a two-phase thermal management device, the frame including an opening, wherein the frame and the two-phase thermal management device define a cavity; and
coupling an electromagnetic interference (EMI) shield structure to the two-phase thermal management device via an EMI shield gasket, such that at least a portion of the EMI shield structure is positioned within the cavity.

16. The method of claim 15, further comprising forming a copper structure within the cavity on a surface of the two-phase thermal management device.

17. The method of claim 15, further comprising obtaining the EMI shield structure that includes:
a base member portion that defines:
a first opening on a first side of the base member portion; and
a second opening on a second side of the base member portion; and
one or more wall portions that extend from the second side of the base member portion.

18. The method of claim 17, further comprising coupling the EMI shield gasket to the first side of the EMI shield structure prior to coupling the EMI shield gasket to the two-phase thermal management device.

19. The method of claim 17, further comprising:
obtaining a printed circuit board (PCB) coupled to a semiconductor integrated circuit (IC) device and a thermal interface material (TIM), the semiconductor IC device is positioned between the PCB and the TIM; and
coupling the EMI shield structure to the PCB.

20. The method of claim 19, wherein coupling the EMI shield structure to the PCB includes passing at least a portion of the TIM through the first opening of the base member portion and the second opening of the base member portion of the EMI shield structure.
